(19) United States
(12) Patent Application Publication
(10) Pub. No.: US 2020/0356109 A1
(43) Pub. Date: Nov. 12, 2020

(54) SENSOR AND COMBINED MAGNETIC NAVIGATION SENSOR

(71) Applicants: Fu Tai Hua Industry (Shenzhen) Co., Ltd., Shenzhen (CN); HON HAI PRECISION INDUSTRY CO., LTD., New Taipei (TW)

(72) Inventors: EDDY LIU, New Taipei (TW); WEI-DA YANG, New Taipei (TW); XIAO-MING LV, Shenzhen (CN); SHU-FA JIANG, Shenzhen (CN); SHUANG-WEN CHEN, Shenzhen (CN)

(21) Appl. No.: 16/564,154

(22) Filed: Sep. 9, 2019

(30) Foreign Application Priority Data
May 10, 2019 (CN) 201910386929.5

(51) Int. Cl. G05D 1/02; G01R 33/07; G01C 21/08

(52) U.S. Cl. CPC G05D 1/0263; G05D 2201/02; G01C 21/08; G01R 33/072

(57) ABSTRACT

A magnetic stripe sensor adaptable for different automated guided vehicles and with enhanced precision of guidance includes a main body, a plurality of first assembly members, and a plurality of second assembly members. The first assembly members and the second assembly members are respectively fixed to a first and a second surface of the main body. Each assembly member defines a slot, and each second assembly member includes a guiding block. The size and shape of the guiding block matches those of the slot, allowing combinations of first and second assembly members as desired. A combined magnetic navigation sensor assembled from first and second assembly members is also disclosed.

### FIELD

The subject matter herein generally relates to AGV navigation.

### BACKGROUND

Magnetic navigation sensors are mainly used in automated guided vehicles (AGVs) such as mobile robots, indoor and outdoor inspection robots, and automatic trolleys, for detection of preset navigation routes and repositioning of the AGV. Taking an AGV as an example, when a magnetic sensor detects a magnetic track, the AGV follows the magnetic track. If the AGV deviates from the magnetic track, signals from the sensor will change. A control unit captures the change of signals from the sensor and steers the AGV back to the magnetic track. At present, 8-point or 16-point integrated magnetic navigation sensors with a spacing of 10 mm are generally used. However, such an integrated magnetic navigation sensor is costly, and is not fully utilized in many applications which do not need so many points. Furthermore, the present integrated magnetic navigation sensors do not have high guiding precision.

Therefore, there is room for improvement.

### BRIEF DESCRIPTION OF THE DRAWINGS

Implementations of the present technology will now be described, by way of embodiments, with reference to the attached figures.

FIG. 1 is an isometric view of a sensor according to an embodiment of the present disclosure.

FIG. 2 is an isometric view of the sensor of FIG. 1 from another angle.

FIG. 3 is an exploded view of the sensor of FIG. 1.

FIG. 4 is an isometric view of a combined magnetic navigation sensor in accordance with an embodiment of the present disclosure.

FIG. 5 is an isometric view of a combined magnetic navigation sensor according to another embodiment of the present disclosure.

### DETAILED DESCRIPTION

The present disclosure is made in conjunction with the accompanying drawings. Specific embodiments of the present disclosure are described.

In the following description, when an element is described as being “fixed to” another element, the element can be fixed to another element with or without intermediate elements. When an element is described as “connecting” another element, the element can be connected to the other element with or ithout intermediate elements, and in a physical or a mechanical way.

Without a given definition otherwise, all terms used have the same meaning as commonly understood by those skilled in the art. The term “and/or” means including any and all combinations of one or more of associated listed items.

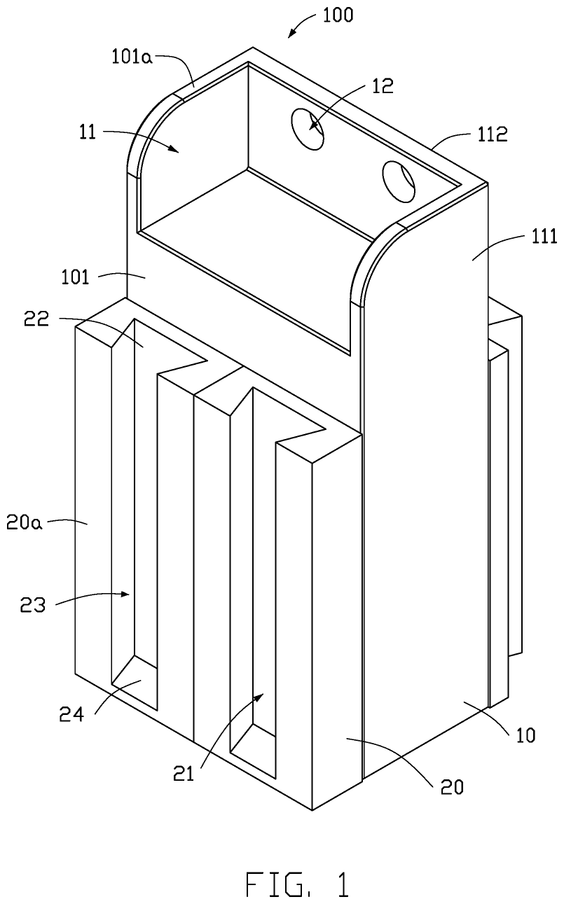

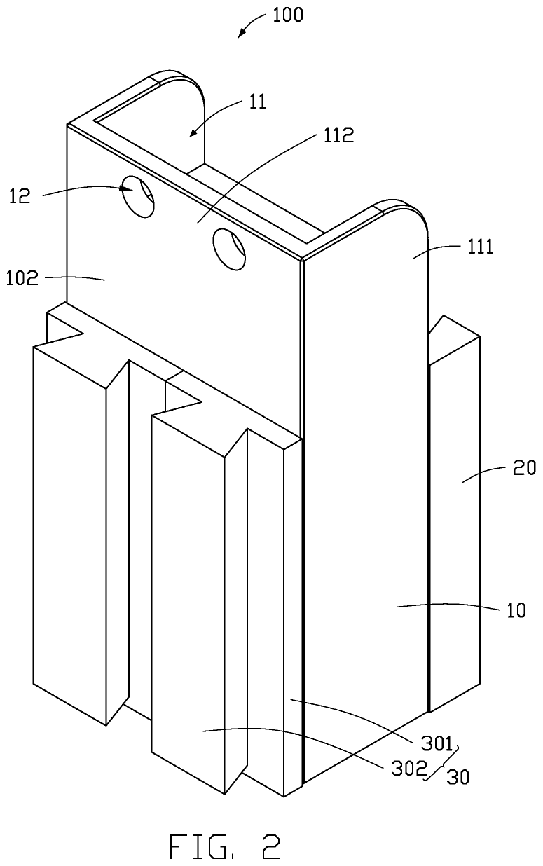

Referring to FIG. 1 and FIG. 2, an embodiment of the present disclosure provides a sensor 100. The sensor 100 includes a main body 10, a plurality of first assembly members 20, and a plurality of second assembly members 30.

In the present embodiment, the main body 10 is a substantially rectangular parallelepiped structure, and includes a first surface 101 and a second surface 102 opposite to the first surface 101. An end portion 101a of the first surface 101 is recessed toward the second surface 102 from the first surface 101 to form a notch 11, and the notch 11 runs through the end portion 101a connecting the first surface 101 and the second surface 102. The notch 11 is surrounded by two opposite sidewalls iii and a bottom wall 112. The bottom wall 112 defines at least one through hole 12. In the embodiment, the bottom wall 112 defines two through holes 12. A central axis of each of the through holes 12 is perpendicular to the first surface 101 and the second surface 102. The main body 10 can be fixed to an external device (not shown) through the through hole 12. The main body 10 has a sensing point (not shown) that senses a magnetic stripe and produces a signal. The main body 10 processes the signal, and converting the signal into an electrical or other desired form of signal.

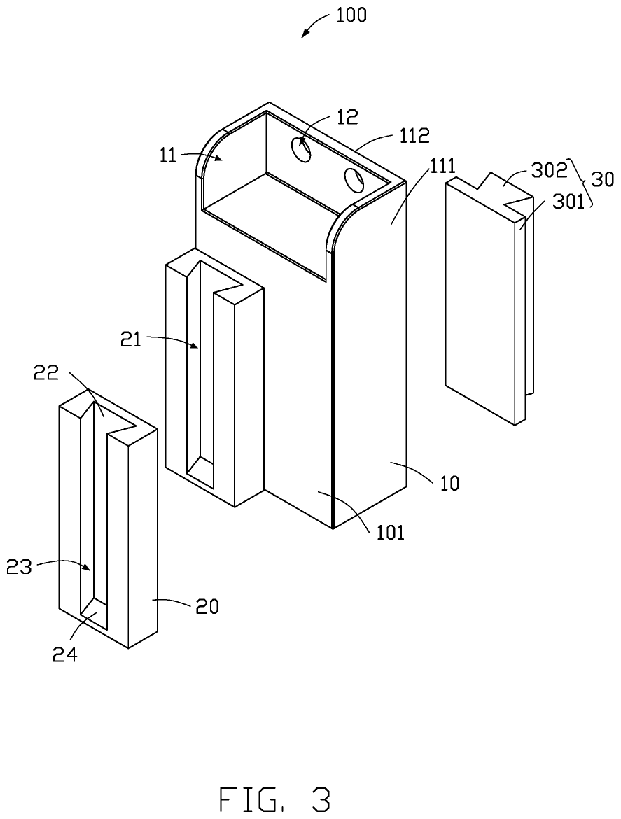

Referring to FIG. 3, the first assembly member 20 is adhesively fixed to the first surface 101. In the embodiment, two first assembly members 20 are fixed side by side on the first surface 101. Each of the first assembly members 20 has a surface 20a away from the main body 10. Each of the surfaces 20a is recessed toward the main body 10 to form a slot 21. Each of the slots 21 has a bottom surface 22 parallel to the first surface 101 and an opening 23 opposite to the bottom surface 22. Each of the slots 21 is dovetailed in cross section, with a width of the bottom surface 22 (that is, the innermost surface) greater than a width of the opening 23.

In the embodiment, each of the slots 21 further has an end surface 24 at an end of the slot 21 which is perpendicular to the bottom surface 22.

The second assembly member 30 is adhesively fixed to the second surface 102. In the embodiment, two second assembly members 30 are fixed on the second surface 102 side by side. Each of the second assembly members 30 includes a fixing plate 301 and a guiding block 302. Each of the fixing plates 301 is fixed to the second surface 102, and each of the guiding blocks 302 is formed on a fixing plate 301 away from the second surface 102. Each of the guiding blocks 302 has a shape and a size matching the slots 21, so that the guiding block 302 can fit the slot 21 of another sensor 100. When the second assembly member 30 of one sensor 100 can be assembled to the first assembly member 20 of another sensor 100, combinations of different numbers of sensors 100 can be realized, so that sensors with different numbers of sensing points can be combined together to correspond to different applications. The fixing plate 301 and the guiding block 302 can be assembled together or can be integrally formed. In the present embodiment, the fixing plate 301 is integrally formed with the guiding block 302. The guiding block 302 is a trapezoidal guide.

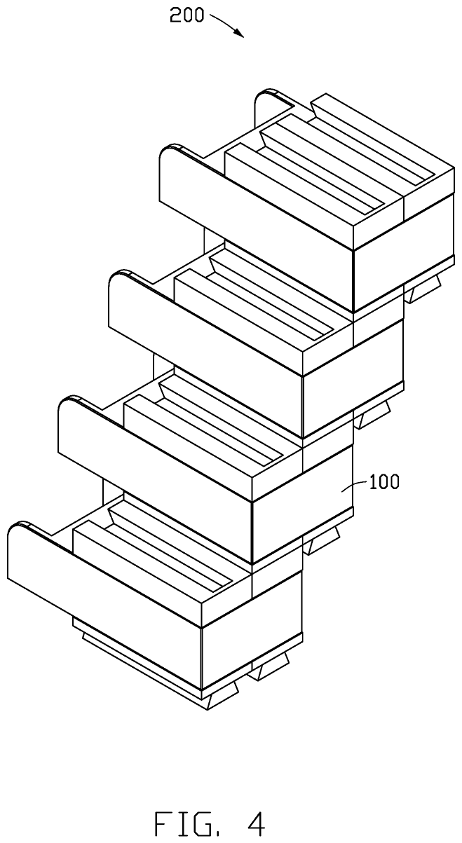

Referring to FIG. 4, the present disclosure further provides a combined magnetic navigation sensor 200 including a plurality of sensors 100 assembled together. The sensors 100 are assembled together by engaging the guiding block 302 of one sensor 100 with the slot 21 of another sensor 100. The guiding block 302 abuts against the end surface 24 of the slot 21 to fix a combination of the sensors 100 in position. Existing 8-point or 16-point integrated magnetic navigation sensors generally define a distance between two adjacent sensing points as 10 mm, such large distance between adjacent sensing points being the reason for low guiding precision of the sensors. The distance between adjacent sensing points of the combined magnetic navigation sensor 200 of the present disclosure is approximately 5 mm, thereby the guiding accuracy is improved.

The combined magnetic navigation sensor 200 includes four sensors 100, the four sensors 100 being assembled and stacked in a stepped shape.

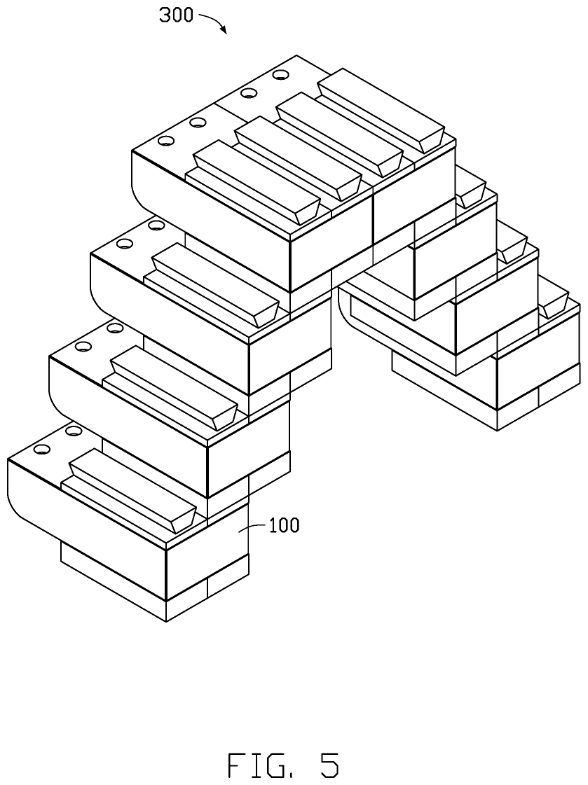

Referring to FIG. 5, the present disclosure provides another combined magnetic navigation sensor 300 that includes eight sensors 100. The eight sensors 100 are assembled. and stacked in a V-shape.

It should be noted that a combined magnetic navigation sensor of the present disclosure can include any number of sensors 100. The combined magnetic navigation sensor can be in stepped form, V-shaped, or in any other shape such as a substantially straight line or an inverted V shape. The sensors 100 can be fitted together into a combined magnetic navigation sensor. Since each of the sensors 100 has a sensing point, a change in the number of sensors 100 or a change of shape of the combined magnetic navigation sensor cause changes to the sensing range and guiding precision of the combined magnetic navigation sensor. Thus, the sensing range of the combined magnetic navigation sensor can be adjusted according to actual needs.

It should be noted that the number of the first assembly members 20 and the number of the second assembly members 30 on each of the sensors 100 can be variable according to actual need. For example, the number of the first assembly members 20 can be three, four, or five, and the number of the second assembly members 30 can be three, four, or five. The number of the first assembly members 20 on a sensor 100 may be equal to or different from the number of the second assembly members 30 on one sensor 100.

The sensor and the combined magnetic navigation sensor provided by the present disclosure allows assembly and disassembly of the sensors by the engagement of the guiding block and the slot. Magnetic navigation guiding precision and the number of sensing points can be adjusted for different applications and is flexible.

The embodiments shown and described above are only examples. Even though numerous characteristics and advantages of the present technology have been set forth in the foregoing description, together with details of the structure and function of the present disclosure, the disclosure is illustrative only, and changes can be made in the detail, including in matters of shape, size, and arrangement of the parts within the principles of the present disclosure, up to and including the full extent established by the broad general meaning of the terms used in the claims.

What is claimed is:

1. A sensor comprising a main body, a plurality of first assembly members, and a plurality of second assembly members, wherein the main body comprises a first surface and a second surface opposite to the first surface, the first assembly members and the second assembly members are respectively fixed to the first surface and the second surface, each of the first assembly members defines a slot, and each of the second assembly members comprises a guiding block, the guiding block having a shape and a size matching with a shape and a size of the slot correspondingly.

2. The sensor according to claim 1, wherein the plurality of first assembly members are fixed side by side on the first surface.

3. The sensor according to claim 1, wherein the plurality of second assembly members are fixed side by side on the second surface.

4. The sensor according to claim 1, wherein the slot is defined on each of the first assembly member away from the first surface, each of the second assembly member further comprises a fixing plate, the fixing plate is fixed to the second surface, and the guiding block is formed on the fixing plate away from the second surface.

5. The sensor according to claim 1, wherein the slot is a dovetail slot, and the guiding block is a trapezoidal guide matching the slot.

6. The sensor according to claim 5, wherein the slot comprises an end surface configured for positioning when the slot is engaging with a guiding block of another sensor.

7. The sensor according to claim 1, wherein an end portion of the first surface is recessed toward the second surface from the first surface to form a notch, the notch runs through an end portion connecting the first surface and the second surface and is surrounded by two opposite sidewalls and a bottom wall, and the bottom wall defines at least one through hole for fixing the main body to an external device.

8. The sensor according to claim 1, wherein the main body has a sensing point.

9. A combined magnetic navigation sensor comprising a plurality of sensors, wherein each of the sensors comprises a main body, a plurality of first assembly members, and a plurality of second assembly members, the main body comprises a first surface and a second surface opposite to the first surface, the first assembly members and the second assembly members are respectively fixed to the first surface and the second surface, each of the first assembly members defines a slot, and each of the second assembly members comprises a guiding block, the guiding block having a shape and a size matching with a shape and a size of the slot correspondingly, the plurality of sensors are assembled together by engaging a guiding block of one of the plurality of sensors in a slot of another one of the plurality of sensors.

10. The combined magnetic navigation sensor according to claim 9, wherein the plurality of first assembly members are fixed side by side on the first surface.

11. The combined magnetic navigation sensor according to claim 9, wherein the plurality of second assembly members are fixed side by side on the second surface.

12. The combined magnetic navigation sensor according to claim 9, wherein the slot is defined on each of the first assembly member away from the first surface, each of the second assembly member further comprises a fixing plate, the fixing plate is fixed to the second surface, and the guiding block is formed on the fixing plate away from the second surface.

13. The combined magnetic navigation sensor according to claim 9, wherein the slot is a dovetail slot, and the guiding block is a trapezoidal guide matching the slot.

14. The combined magnetic navigation sensor according to claim 13, wherein the slot comprises an end surface configured for positioning when the slot are engaging with a guiding block of another one of the plurality of sensors

15. The combined magnetic navigation sensor according to claim 9, wherein an end portion of the first surface is recessed toward the second surface from the first surface to form a notch, the notch runs through an end portion connecting the first surface and the second surface and is surrounded by two opposite sidewalls and a bottom wall, and the bottom wall defines at least one through hole for fixing the main body to an external device.

16. The combined magnetic navigation sensor according to claim 9, wherein the main body of each of the plurality of sensors has a sensing point, and different combinations of the plurality of sensors bring about mutual positional changes between the sensing points.
